(19) United States
(12) Patent Application Publication
(10) Pub. No.: US 2026/0047162 A1
(43) Pub. Date: Feb. 12, 2026

(54) TRANSISTOR AND METHOD FOR MANUFACTURING SAME

(71) Applicant: Microchip Technology Incorporated, Chandler, AZ (US)

(72) Inventors: Sergey Maximenko, Colorado Springs, CO (US); Bruce Odekirk, Portland, OR (US)

(73) Assignee: Microchip Technology Incorporated, Chandler, AZ (US)

(21) Appl. No.: 19/038,855

(22) Filed: Jan. 28, 2025

Related U.S. Application Data
(60) Provisional application No. 63/680,153, filed on Aug. 7, 2024.

(51) Int. Cl. H10D 62/60; H10D 30/01; H10D 30/66; H10D 62/13; H10D 62/832

(52) U.S. Cl. CPC H10D 62/60; H10D 30/0297; H10D 30/668; H10D 62/153; H10D 62/154; H10D 62/155; H10D 62/8325

(57) ABSTRACT

A transistor comprising a silicon carbide drain contact formed at a first side of a silicon carbide substrate and a silicon carbide drift layer formed at a second side of the silicon carbide substrate. A well implant layer and a base layer formed within the silicon carbide drift layer. A source layer formed over the base layer. A trench formed through a portion of the source layer, through a portion of the base layer and partially into a portion of the well implant layer wherein only one wall of the trench is tapered. A gate formed within the trench.

### CROSS-REFERENCE TO RELATED APPLICATION

The present application claims priority to U.S. Provisional Patent Application No. 63/680,153 filed on Aug. 7, 2024, the contents of which are hereby incorporated by reference in their entirety.

### TECHNICAL FIELD

The present disclosure relates generally to transistors, and more specifically to power metal oxide semiconductor field effect transistors (MOSFETs) with an asymmetric trench and methods for manufacturing same to improve the current density (and consequently the power density) of the transistor.

### SUMMARY

According to an aspect of one or more examples, there is provided a transistor that may include a silicon carbide substrate, a silicon carbide drain contact formed at a first side of the silicon carbide substrate, a silicon carbide drift layer formed at a second side of the silicon carbide substrate, a well implant layer within the silicon carbide drift layer, a base layer formed within the silicon carbide drift layer, a source layer formed over the base layer, a trench formed through a portion of the source layer, through a portion of the base layer and partially into a portion of the well implant layer wherein only one wall of the trench is tapered, and a gate formed within the trench. The one side tapered wall of the trench may coincide with a 0-33-8 plane of the silicon carbide substrate. The silicon carbide substrate may comprise a first concentration of a first type dopant. The silicon carbide drift layer may comprise a second concentration of the first type dopant, the first concentration may be greater than the second concentration. The well implant layer may comprise a third concentration of a second type dopant. The base layer may comprise a fourth concentration of the second type dopant, the third concentration may be greater than the fourth concentration. The source layer may comprise a fifth concentration of the first type dopant. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided method of manufacturing a transistor. The method may include providing a silicon carbide substrate, forming a silicon carbide drain contact at a first side of the silicon carbide substrate, forming a silicon carbide drift layer at a second side of the silicon carbide substrate, forming a well implant layer within the silicon carbide drift layer, forming a base layer within the silicon carbide drift layer, forming a source layer over the base layer, forming a trench having only one tapered wall through a portion of the source layer, through a portion of the base layer and partially into a portion of the well implant layer, and forming a gate formed within the trench. The one side tapered wall of the trench may coincide with a 0-33-8 plane of the silicon carbide substrate. The silicon carbide substrate may comprise a first concentration of a first type dopant. The silicon carbide drift layer may comprise a second concentration of the first type dopant, the first concentration may be greater than the second concentration. The well implant layer may comprise a third concentration of a second type dopant. The base layer may comprise a fourth concentration of the second type dopant, the third concentration may be greater than the fourth concentration. The source layer may comprise a fifth concentration of the first type dopant. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 shows an illustration of a transistor having a tapered trench according to one or more examples.

FIG. 2A is a cross sectional view of some of the steps in a method of manufacturing a transistor having a tapered trench according to one or more examples.

FIG. 2B is a cross sectional view of some of the steps in a method of manufacturing a transistor having a tapered trench according to one or more examples.

FIG. 3A is a cross sectional view of some of the steps in a method of manufacturing a transistor having a tapered trench according to one or more examples.

FIG. 3B is a cross sectional view of some of the steps in a method of manufacturing a transistor having a tapered trench according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

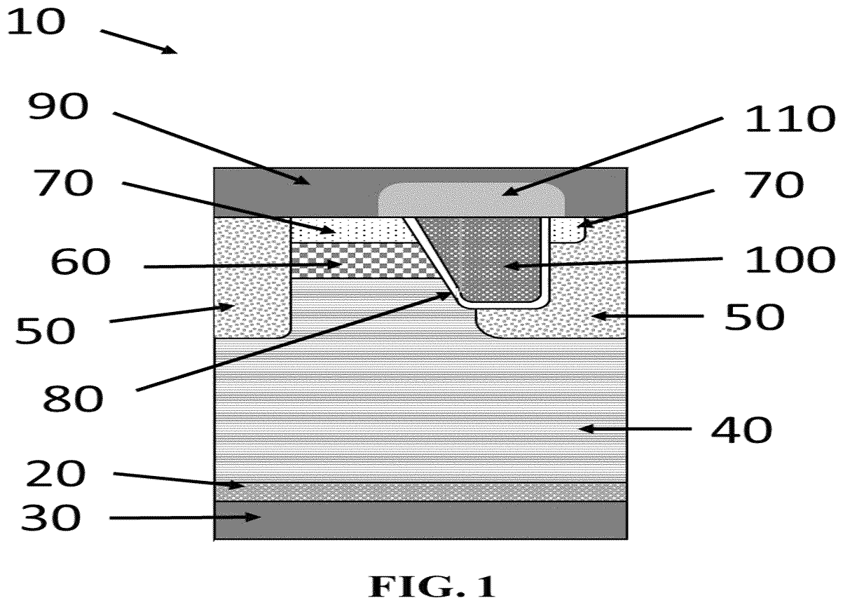

FIG. 1 shows an illustration of a transistor 10 having a tapered trench 80 according to one or more examples. Transistor 10 may represent, and may be called a power MOSFET, without limitation. Transistor 10 includes an insulating film 110, a source contact 90 and a drain contact 30 (may comprise a metal). The example transistor 10 (power MOSFET) of FIG. 1 includes a silicon carbide (SiC) substrate 20. The SiC substrate 20 shown in FIG. 1 may have a first concentration of a first type dopant, e.g., 1E18 (i.e. 1×10¹⁸). A drain contact 30 may be formed at one side of the SiC substrate 20. The transistor 10 of FIG. 1 may also include a silicon carbide drift layer 40 formed at a second side of the silicon carbide substrate 20. The silicon carbide drift layer 40 may comprise a second concentration of the first type dopant wherein the first concentration of the silicon carbide substrate 20 may be greater than the second concentration of the silicon carbide drift layer 40. The transistor 10 of FIG. 1 may also include a well implant layer 50 that may be formed within the silicon carbide drift layer 40. The well implant layer 50 may comprise a third concentration of a second type dopant. The transistor 10 of FIG. 1 may also include a base layer 60 that may be formed within the silicon carbide drift layer 40. The base layer 60 may comprise a fourth concentration of the second type dopant wherein the third concentration of the well implant layer 50 may be greater than the fourth concentration of the base layer 60. The transistor 10 of FIG. 1 may also include a source layer 70 formed over the base layer 60. The source layer may comprise a fifth concentration of the first type dopant. The transistor 10 of FIG. 1 may also include a trench 80 formed through a portion of the source layer 70, through a portion of the base layer 60 and partially into a portion of the well implant layer 50 wherein only one wall of the trench 80 is tapered. The one side tapered wall of the trench 80 may coincide with a 0-33-8 plane of the silicon carbide substrate 20. The 0-33-8 plane of the silicon carbide substrate 20 enhances the current density (and consequently the power density) of the switching device. The transistor 10 of FIG. 1 may also include a gate 100 formed within the trench 80. The gate 100 may be made from a metal, polysilicon, or other suitable material.

In the example transistor 10 of FIG. 1, the first type dopant may be an n-type dopant with the second type dopant being a p-type dopant. Alternatively, the first type dopant may be a p-type dopant with the second type dopant being an n-type dopant.

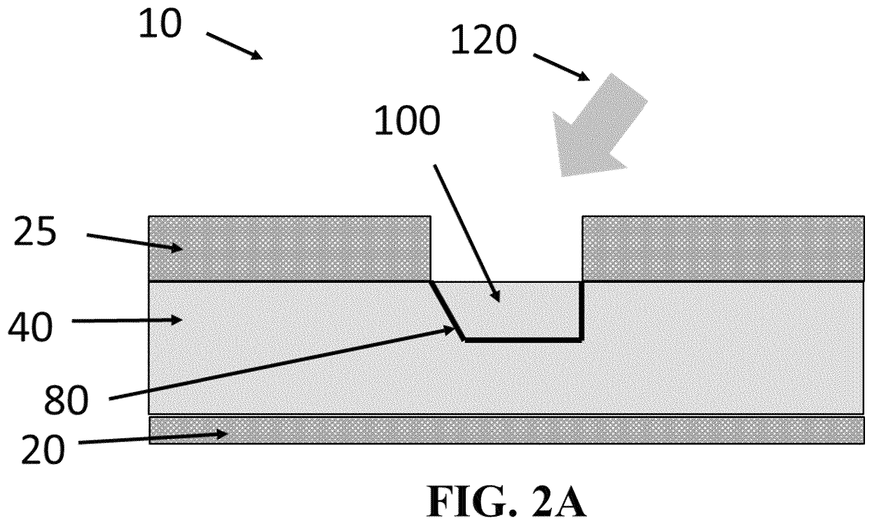

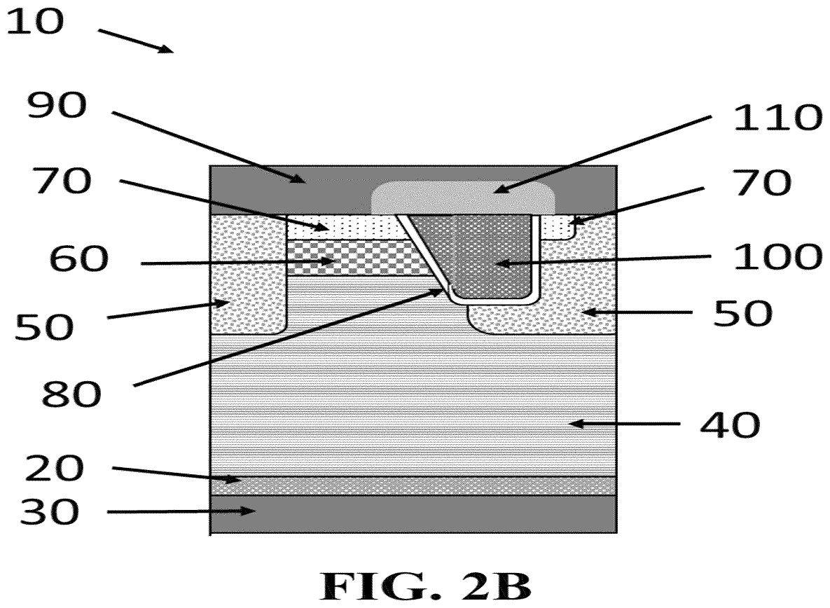

FIGS. 2A-2B show a method of manufacturing transistor 10 having a tapered trench 80 according to one or more examples. Although the example method shown in FIGS. 2A-2B include steps shown in a particular order, the steps may be performed in a different order, and may include additional steps that are not explicitly shown.

FIG. 2A is a cross sectional view of some of the steps in a method of manufacturing a transistor 10 having a tapered trench 80 according to one or more examples. In FIG. 2A, the example method may include forming a hard mask 25 having a perpendicular opening within a drift layer 40 for using a tilted ion beam 120 to implant the gate 100 within a trench 80 wherein only one wall of the trench 80 is tapered. The one side tapered wall of the trench 80 may coincide with a 0-33-8 plane of the silicon carbide substrate 20. The 0-33-8 plane of the silicon carbide substrate 20 enhances the current density (and consequently the power density) of the switching device.

FIG. 2B is a cross sectional view of some of the steps in a method of manufacturing a transistor 10 having a tapered trench 80 according to one or more examples. In FIG. 2B, a silicon carbide (SiC) substrate 20 may be provided. The SiC substrate 20 shown in FIG. 2B may have a first concentration of a first type dopant, e.g., 1E18 (i.e. 1×10¹⁸). A drain contact 30 may be formed at one side of the SiC substrate 20. The transistor of FIG. 2B may also include a silicon carbide drift layer 40 formed at a second side of the silicon substrate 20. The silicon carbide drift layer 40 may comprise a second concentration of the first type dopant wherein the first concentration of the silicon carbide substrate 20 may be greater than the second concentration of the silicon carbide drift layer 40. The transistor 10 of FIG. 2B may also include a well implant layer 50 that may be formed within the silicon carbide drift layer 40. The well implant layer 50 may comprise a third concentration of a second type dopant. The transistor 10 of FIG. 2B may also include a base layer 60 that may be formed within the silicon carbide drift layer 40. The base layer 60 may comprise a fourth concentration of the second type dopant wherein the third concentration of the well implant layer 50 may be greater than the fourth concentration of the base layer 60. The transistor 10 of FIG. 2B may also include a source layer 70 formed over the base layer 60. The transistor 10 of FIG. 2B may also include a trench 80 formed through a portion of the source layer 70, through a portion of the base layer 60 and partially into a portion of the well implant layer 50 wherein only one wall of the trench 80 is tapered. The one side tapered wall of the trench 80 may coincide with a 0-33-8 plane of the silicon carbide substrate 20. The 0-33-8 plane of the silicon carbide substrate 20 enhances the current density (and consequently the power density) of the switching device. The transistor 10 of FIG. 2B may also include a gate 100 formed within the trench 80. The gate 100 may be made from a metal, polysilicon, or other suitable material. The transistor 10 may include an insulating film 110, a source contact 90 and a drain contact 30 that may comprise a metal.

The example method of manufacturing transistor 10 having a tapered trench 80 of FIGS. 2A-2B may have the first type dopant be an n-type dopant with the second type dopant being a p-type dopant. Alternatively, the first type dopant may be a p-type dopant with the second type dopant being an n-type dopant.

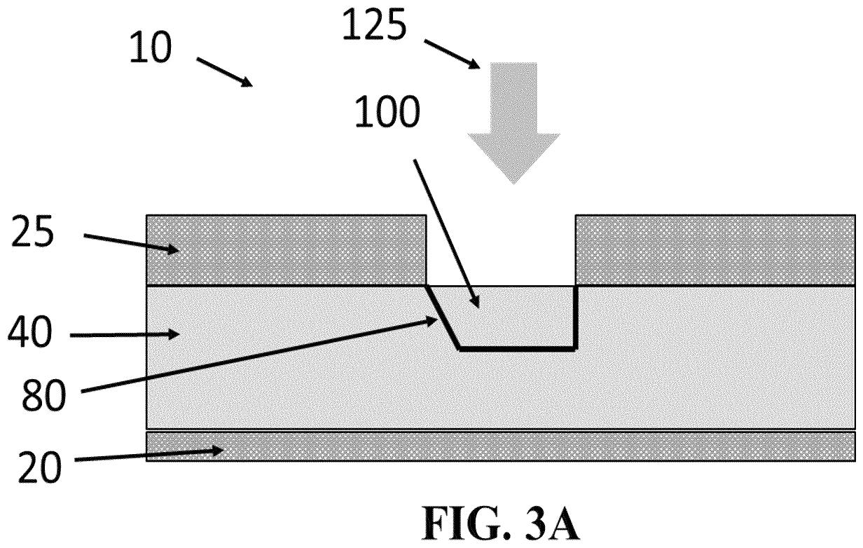

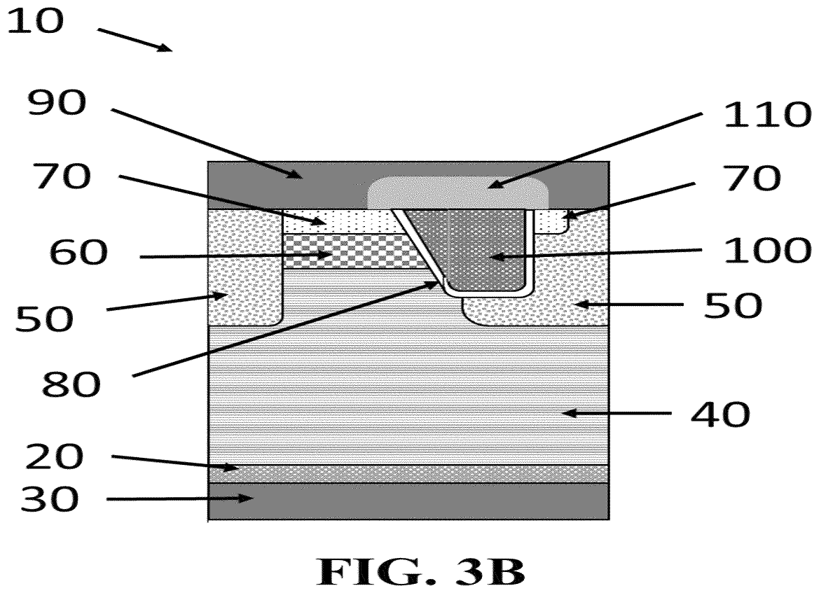

FIGS. 3A-3B show a method of manufacturing transistor having a tapered trench according to one or more examples. Although the example method shown in FIGS. 3A-3B include steps shown in a particular order, the steps may be performed in a different order, and may include additional steps that are not explicitly shown.

FIG. 3A is a cross sectional view of some of the steps in a method of manufacturing a transistor 10 having a tapered trench 80 according to one or more examples. In FIG. 3A, the example method may include forming a hard mask 25 having a perpendicular opening within a drift layer 40 for using a perpendicularly aimed ion beam 125 to implant the gate 100 within a trench 80 wherein only one wall of the trench 80 is tapered. The one side tapered wall of the trench 80 may coincide with a 0-33-8 plane of the silicon carbide substrate 20. The 0-33-8 plane of the silicon carbide substrate 20 enhances the current density (and consequently the power density) of the switching device.

FIG. 3B is a cross sectional view of some of the steps in a method of manufacturing a transistor 10 having a tapered trench 80 according to one or more examples. In FIG. 3B, a silicon carbide (SiC) substrate 20 may be provided. The SiC substrate 20 shown in FIG. 3B may have a first concentration of a first type dopant, e.g., 1E18 (i.e. 1×10¹⁸). A drain contact 30 may be formed at one side of the SiC substrate 20. The transistor of FIG. 3B may also include a silicon carbide drift layer 40 formed at a second side of the silicon substrate 20. The silicon carbide drift layer 40 may comprise a second concentration of the first type dopant wherein the first concentration of the silicon carbide substrate 20 may be greater than the second concentration of the silicon carbide drift layer 40. The transistor 10 of FIG. 3B may also include a well implant layer 50 that may be formed within the silicon carbide drift layer 40. The well implant layer 50 may comprise a third concentration of a second type dopant. The transistor 10 of FIG. 3B may also include a base layer 60 that may be formed within the silicon carbide drift layer 40. The base layer 60 may comprise a fourth concentration of the second type dopant wherein the third concentration of the well implant layer 50 may be greater than the fourth concentration of the base layer 60. The transistor 10 of FIG. 3B may also include a source layer 70 formed over the base layer 60. The transistor 10 of FIG. 3B may also include a trench 80 formed through a portion of the source layer 70, through a portion of the base layer 60 and partially into a portion of the well implant layer 50 wherein only one wall of the trench 80 is tapered. The one side tapered wall of the trench 80 may coincide with a 0-33-8 plane of the silicon carbide substrate 20. The 0-33-8 plane of the silicon carbide substrate 20 enhances the current density (and consequently the power density) of the switching device. The transistor 10 of FIG. 3B may also include a gate 100 formed within the trench 80. The gate 100 may be made from a metal, polysilicon, or other suitable material. The transistor 10 may include an insulating film 110, a source contact 90 and a drain contact 30 that may comprise a metal.

The example method of manufacturing transistor 10 having a tapered trench 80 of FIGS. 3A-3B may have the first type dopant be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a silicon carbide substrate;
a silicon carbide drain contact formed at a first side of the silicon carbide substrate;
a silicon carbide drift layer formed at a second side of the silicon carbide substrate;
a well implant layer formed within the silicon carbide drift layer;
a base layer formed within the silicon carbide drift layer;
a source layer formed over the base layer;
a trench formed through a portion of the source layer, through a portion of the base layer and partially into a portion of the well implant layer wherein only one wall of the trench is tapered; and
a gate formed within the trench.

2. The transistor of claim 1, wherein the one side tapered wall of the trench coincides with a 0-33-8 plane of the silicon carbide substrate.

3. The transistor of claim 1, wherein the silicon carbide substrate comprises a first concentration of a first type dopant.

4. The transistor of claim 3, wherein the silicon carbide drift layer comprises a second concentration of the first type dopant, the first concentration is greater than the second concentration.

5. The transistor of claim 4, wherein the well implant layer comprises a third concentration of a second type dopant.

6. The transistor of claim 5, wherein the base layer comprises a fourth concentration of the second type dopant, the third concentration is greater than the fourth concentration.

7. The transistor of claim 6, wherein the source layer comprises a fifth concentration of the first type dopant.

8. The transistor of claim 7, wherein the first type dopant comprises an n-type dopant and the second type dopant comprises a p-type dopant.

9. The transistor of claim 7, wherein the first type dopant comprises a p-type dopant and the second type dopant comprises an n-type dopant.

10. A method of manufacturing a transistor, the method comprising:
providing a silicon carbide substrate;
forming a silicon carbide drain contact at a first side of the silicon carbide substrate;
forming a silicon carbide drift layer at a second side of the silicon carbide substrate;
forming a well implant layer within the silicon carbide drift layer;
forming a base layer within the silicon carbide drift layer;
forming a source layer over the base layer;
forming a trench through a portion of the source layer, through a portion of the base layer and partially into a portion of the well implant layer wherein only one wall of the trench is tapered; and
forming a gate within the trench.

11. The method of claim 10, wherein the one side tapered wall of the trench coincides with a 0-33-8 plane of the silicon carbide substrate.

12. The method of claim 10, wherein the silicon carbide substrate comprises a first concentration of a first type dopant.

13. The method of claim 12, wherein the silicon carbide drift layer comprises a second concentration of the first type dopant, the first concentration is greater than the second concentration.

14. The method of claim 13, wherein the well implant layer comprises a third concentration of a second type dopant.

15. The method of claim 14, wherein the base layer comprises a fourth concentration of the second type dopant, the third concentration is greater than the fourth concentration.

16. The method of claim 15, wherein the source layer comprises a fifth concentration of the first type dopant.

17. The method of claim 16, wherein the first type dopant comprises an n-type dopant and the second type dopant comprises a p-type dopant.

18. The method of claim 16, wherein the first type dopant comprises a p-type dopant and the second type dopant comprises an n-type dopant.
